(19) United States
(12) Patent Application Publication
(10) Pub. No.: US 2008/0296772 A1
(43) Pub. Date: Dec. 4, 2008

(54) Semicondutor device

(75) Inventors: Yuichi Nakao, Kyoto (JP); Takahisa Yamaha, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/155,231

(22) Filed: May 30, 2008

(30) Foreign Application Priority Data
May 31, 2007 (JP) 2007-145808

(51) Int. Cl. H01L 23/48

(52) U.S. Cl. 257/761; 257/E23.141

(57) ABSTRACT

A semiconductor device according to the present invention includes: a lower wire having copper as a main component; an insulating film formed on the lower wire; an upper wire formed on the insulating film; a tungsten plug penetrating through the insulating film and formed of tungsten for electrically connecting the lower wire and the upper wire; and a barrier layer interposed between the lower wire and the tungsten plug; and the barrier layer including a tantalum film contacting the lower wire and a titanium nitride film contacting the tungsten plug.

### BACKGROUND OF THE INVENTION

1. Field of the Invention

The present invention relates to a semiconductor device with a multilayer wiring structure.

2. Description of Related Art

A so-called multilayer wiring structure, in which a plurality of wiring layers are laminated on a semiconductor substrate, is employed in a semiconductor device, such as an LSI of a high integration.

In semiconductor devices employing such a multilayer wiring structure, in place of Al (aluminum) which has been conventionally used from before as a wiring material, application of copper (copper), which is higher in conductivity is being studied in order to reduce wiring resistance.

In a multilayer wiring structure using a copper wiring material, a first insulating film formed of SiO₂ (silicon oxide) is laminated onto a semiconductor substrate formed of Si (silicon). A microscopic wiring groove corresponding to a predetermined wiring pattern is formed in a surface layer portion of the first insulating film. In the wiring groove, a first copper wire is embedded via a Ta (tantalum-based) barrier film for preventing diffusion of copper into the insulating film.

A second insulating film formed of SiO₂ is laminated on the first insulating film. A microscopic wiring groove corresponding to a predetermined wiring pattern is formed in the second insulating film. Furthermore, in the second insulating film a via hole is penetratingly formed at a portion where the wiring groove opposes the first copper wire. A second copper wire is embedded together in the wiring groove and the via hole via a Ta (tantalum-based) barrier film for preventing diffusion of copper into the insulating film. The second copper wire is thereby electrically connected to the first copper wire. Thus, a multilayer wiring structure using copper wires is formed.

A third insulating film formed of SiO₂ is laminated on the second insulating film. An Al wire of a predetermined wiring pattern formed of Al (aluminum) is formed on the third insulating film. Furthermore, in the third insulating film, a via hole is penetratingly formed at a portion where the Al wire opposes the second copper wire. The Al wire and the second wire are connected via a W (tungsten) plug provided in the via hole.

In a case where the W plug is formed, for example, by a CVD method using WF₆ gas (tungsten hexafluoride gas), a barrier film is provided between the W plug and the third insulating film to prevent diffusion of the WF₆ gas into the third insulating film. When a Ti material is used as a material of the barrier film, Cu and Ti may react at a portion where the barrier film contacts the second Cu wire to corrode the second Cu wire. When the second copper wire corrodes, so-called electromigration may occur.

It has thus been proposed to use a Ta material having a low reactivity with Cu as the barrier film interposed between the W plug and the third insulating film.

However, in order to prevent the diffusion of WF₆ gas into the insulating film by a barrier film using a Ta material, the barrier film must be thick in film thickness. However, if the barrier film is thick in film thickness, the W plug has high aspect ratio to narrow a contact area of the barrier film and the W plug. In addition, adhesion of a Ta material and W is not always high. Peeling of the barrier film may thus occur when an external force is applied to the semiconductor device and so-called stress migration may occur.

### SUMMARY OF THE INVENTION

An object of the present invention is to provide a semiconductor device having excellent stress migration resistance and electromigration resistance and high reliability of connection of a lower wire and an upper wire.

A semiconductor device according to the present invention includes: a lower wire having copper as a main component; an insulating film formed on the lower wire; an upper wire formed on the insulating film; a tungsten plug penetrating through the insulating film and formed of tungsten for electrically connecting the lower wire and the upper wire; and a barrier layer interposed between the lower wire and the tungsten plug; the barrier layer including a tantalum film contacting the lower wire and a titanium nitride film contacting the tungsten plug.

According to this arrangement, the insulating film is formed on the lower wire having copper as the main component. The upper wire is formed on the insulating film. The lower wire and the upper wire are electrically connected with the tungsten plug that is formed of tungsten and penetrates through the insulating film. The barrier layer is interposed between the lower wire and the tungsten plug. The barrier layer includes the tantalum film contacting the lower wire and the titanium nitride film contacting the tungsten plug.

The titanium nitride film is the portion of the barrier layer that contacts the tungsten plug. Thus even when the tungsten plug is formed by a CVD method using WF₆ gas (tungsten hexafluoride gas), the WF₆ gas can be prevented from diffusing into the insulating film and corroding the insulating film.

Further, because the tungsten plug contacts the titanium nitride film that is excellent in adhesion with tungsten, adhesion of the barrier layer and the tungsten plug can be improved. Meanwhile, because the lower wire contacts the tantalum film that is excellent in adhesion with copper, adhesion of the barrier layer and the lower wire can be improved. Accordingly, layer peeling of the barrier layer can be prevented. Therefore, occurrence of stress migration can be prevented. Furthermore, because the titanium nitride film and the lower wire having copper as the main component are not in contact and because tantalum is low in reactivity with copper, corrosion of the lower wiring does not occur. Thus occurrence of electromigration can be prevented.

Consequently, the reliability of connection of the lower wire and the upper wire can be improved.

Preferably, the barrier layer further includes a tantalum nitride film interposed between the tantalum film and the titanium nitride film.

In comparison to tantalum, tantalum nitride is excellent in an ability to prevent diffusion of copper into SiO₂ (silicon oxide) or other insulating material (copper diffusion preventing performance). Thus by an arrangement in which the tantalum nitride film is interposed between the tantalum film and the titanium nitride film, diffusion of the copper of the lower wire into the insulating film can be prevented.

When the barrier layer includes the tantalum nitride film, the barrier layer preferably further includes a titanium film interposed between the tantalum nitride film and the titanium nitride film. Titanium has excellent adhesion with tantalum nitride and titanium nitride. Thus by an arrangement in which the titanium film is interposed between the tantalum nitride film and the titanium nitride film, adhesion of the tantalum nitride film and the titanium nitride film can be improved. Consequently, layer peeling of the barrier layer can be further prevented.

Preferably, the barrier layer further includes a titanium film interposed between the tantalum film and the titanium nitride film. Because titanium has excellent adhesion also with tantalum, by arranging the barrier layer to have the titanium film interposed between the tantalum film and the titanium nitride film, layer peeling of the barrier layer can be further prevented.

Furthermore, the upper wire is preferably an aluminum wire having aluminum as a main component.

The above and further objects, characteristics, and effects of the present invention shall be made clearer by the following description of embodiments with reference to the attached drawings.

### BRIEF DESCRIPTION OF THE SEVERAL VIEWS OF THE DRAWING

FIG. 1 is a schematic sectional view showing an arrangement of a semiconductor device according to a first embodiment of the present invention.

FIG. 2 is an enlarged view showing a portion surrounded by a circle A in FIG. 1.

FIG. 3A is a schematic sectional view showing a manufacturing step of the semiconductor device shown in FIG. 1.

FIG. 3B is a schematic sectional view showing a step subsequent to FIG. 3A.

FIG. 3C is a schematic sectional view showing a step subsequent to FIG. 3B.

FIG. 3D is a schematic sectional view showing a step subsequent to FIG. 3C.

FIG. 3E is a schematic sectional view showing a step subsequent to FIG. 3D.

FIG. 3F is a schematic sectional view showing a step subsequent to FIG. 3E.

FIG. 3G is a schematic sectional view showing a step subsequent to FIG. 3F.

FIG. 3H is a schematic sectional view showing a step subsequent to FIG. 3G.

FIG. 3I is a schematic sectional view showing a step subsequent to FIG. 3H.

FIG. 3J is a schematic sectional view showing a step subsequent to FIG. 3I.

FIG. 3K is a schematic sectional view showing a step subsequent to FIG. 3J.

FIG. 3L is a schematic sectional view showing a step subsequent to FIG. 3K.

FIG. 3M is a schematic sectional view showing a step subsequent to FIG. 3L.

FIG. 3N is a schematic sectional view showing a step subsequent to FIG. 3M.

FIG. 3O is a schematic sectional view showing a step subsequent to FIG. 3N.

FIG. 3P is a schematic sectional view showing a step subsequent to FIG. 3O.

FIG. 3Q is a schematic sectional view showing a step subsequent to FIG. 3P.

FIG. 4 is a schematic sectional view showing an arrangement of a semiconductor device according to a second embodiment of the present invention.

FIG. 5A is a schematic sectional view for describing a method for forming a structure connecting an aluminum wire (upper wire) and a copper wire (lower wire) that are connected by a tungsten plug.

FIG. 5B is schematic sectional view showing a step subsequent to FIG. 5A.

### DETAILED DESCRIPTION OF THE INVENTION

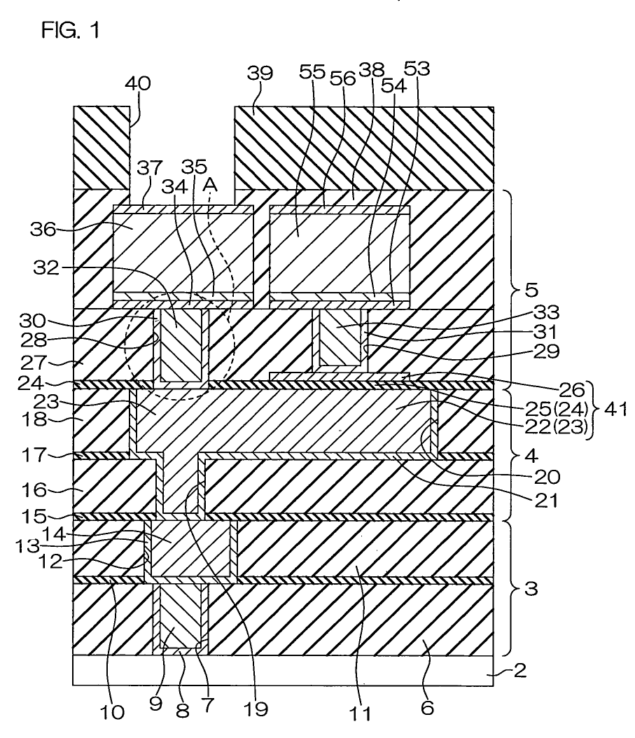

FIG. 1 is a schematic sectional view showing an arrangement of a semiconductor device according to a first embodiment of the present invention.

On a semiconductor substrate 2 formed of Si (silicon), for example, the semiconductor device 1 has a multilayer wiring structure having a first wiring layer 3, a second wiring layer 4, and a third wiring layer 5 laminated in that order starting from the semiconductor substrate 2 side.

A functional device (not shown), such as MOSFET (metal oxide semiconductor field effect transistor), is built on a surface layer portion of the semiconductor substrate 2.

The first wiring layer 3 includes an interlayer film 6 formed of SiO₂ (silicon oxide) and laminated on the semiconductor substrate 2, a diffusion preventing film 10 formed of SiC (silicon carbide) and laminated on the interlayer film 6, and an interlayer film 11 formed of SiO₂ and laminated on the diffusion preventing film 10.

In the interlayer film 11 and the diffusion preventing film 10 a wiring groove 12 of a predetermined pattern is formed that penetrates through these films in a film thickness direction.

In the interlayer film 6, a contact hole 7 penetrating through the interlayer film 6 in the film thickness direction is formed at a portion where the semiconductor substrate 2 and the wiring groove 12 oppose each other. A portion of a surface of the semiconductor substrate 2 that faces the contact hole 7 functions as a contact for electrical contact with the functional device.

A tantalum barrier film 13 is deposited onto side surfaces and a bottom surface of the wiring groove 12. The tantalum barrier film 13 has, for example, a single-layer structure formed of a tantalum film deposited onto the side surfaces and the bottom surface of the wiring groove 12, or a two-layer structure formed of a tantalum nitride film and a tantalum film deposited onto the tantalum nitride film.

A copper wire 14 formed of a metal having copper (copper) as a main component is embedded in the wiring groove 12, onto which the tantalum barrier film 13 is deposited.

A titanium nitride barrier film 8 formed of titanium nitride is deposited onto side surfaces of the contact hole 7 and the portion (contact) of the semiconductor substrate 2 facing the interior of the contact hole 7.

A tungsten plug 9 formed of tungsten is embedded in the contact hole 7 deposited with the titanium nitride barrier film 8. The tungsten plug 9 fills up the contact hole 7 and an upper surface thereof is flush with an upper surface of the interlayer film 6. With the tungsten plug 9, the copper wire 14 and the contact of the semiconductor substrate 2 are electrically connected.

The second wiring layer 4 includes a diffusion preventing film 15 formed of SiC and laminated on the interlayer film 11, an interlayer film 16 formed of SiO₂ and laminated on the diffusion preventing film 15, an etch stop film 17 formed of SiC and laminated on the interlayer film 16, and an interlayer film 18 formed of SiO₂ and laminated on the etch stop film 17.

In the interlayer film 18 and the etch stop film 17, a wiring groove 20 of a predetermined pattern is formed that penetrates through these films in the film thickness direction.

In the interlayer film 16 and the diffusion preventing film 15, a via hole 19 penetrating through these films in the film thickness direction is formed at a portion where the copper wire 14 and the wiring groove 20 oppose each other.

A tantalum barrier film 21 is deposited onto side surfaces and bottom surfaces of the wiring groove 20, side surfaces of the via hole 19, and a portion of the copper wire 14 that faces an interior of the via hole 19.

The tantalum barrier film 21 has, for example, a single-layer structure formed of a tantalum film deposited onto the side surfaces and the bottom surfaces of the wiring groove 20, the side surfaces of the via hole 19, and the portion of the copper wire 14 that faces the interior of the via hole 19, or a two-layer structure formed of a tantalum nitride film and a tantalum film deposited onto the tantalum nitride film.

A copper wiring 23 (lower wiring) formed of a metal having copper as a main component is embedded in the via hole 19 and the wiring groove 20 deposited with the tantalum barrier film 21. The copper wire 23 fills up the wiring groove 20 and an upper surface thereof is flush with an upper surface of the interlayer film 18. The copper wire 23 also fills up the via hole 19. The copper wire 23 is thereby electrically connected to the copper wire 14 via the tantalum barrier film 21.

The third wiring layer 5 includes a diffusion preventing film 24 formed of SiC and laminated on the interlayer film 18, an interlayer film 27 (insulating film) formed of SiO₂ and laminated on the diffusion preventing film 24, and an interlayer film 38 formed of SiO₂ and laminated on the interlayer film 27.

An aluminum wire 36 (upper wire) of a predetermined pattern and made of a metal having aluminum as a main component (for example, an aluminum-copper alloy) is formed in the interlayer film 38. The aluminum wire 36 is sandwiched by a barrier film in a two-layer structure having a titanium nitride barrier film 35 formed of titanium nitride and deposited onto a lower surface of the aluminum wire 36, and a titanium barrier film 34 formed of titanium and deposited onto the titanium nitride barrier film 35, and a titanium nitride barrier film 37 formed of titanium nitride and deposited onto an upper surface of the aluminum wire 36 (hereinafter, unless specified otherwise, the aluminum wire 36 includes the titanium barrier film 34, the titanium nitride barrier film 35, and the titanium nitride barrier film 37). In place of the barrier film in the two-layer structure having the titanium barrier film 34 and the titanium nitride barrier film 35, a single-layer barrier film made of titanium nitride may be formed.

In the interlayer film 27 and the diffusion preventing film 24, a via hole 28 for penetrating through these films in the film thickness direction is formed at a portion where the copper wire 23 and the aluminum wire 36 oppose each other.

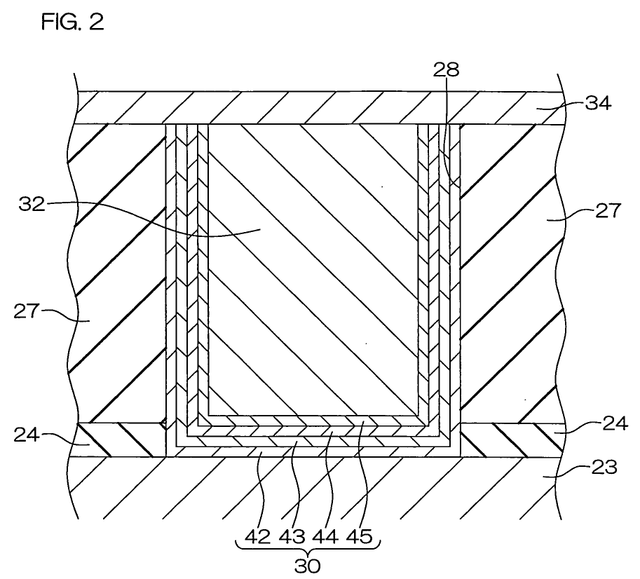

A conductive laminated barrier film 30 is deposited onto side surfaces of the via hole 28 and a portion of the copper wire 23 that faces an interior of the via hole 28. A specific arrangement of the laminated barrier film 30 shall be described in detail later with reference to FIG. 2.

A tungsten plug 32 formed of tungsten is embedded in the via hole 28 deposited with the laminated barrier film 30. The tungsten plug 32 fills up the via hole 28 and an upper surface thereof is flush with an upper surface of the interlayer film 27. The aluminum wire 36 and the copper wire 23 are connected electrically with the tungsten plug 32.

A surface protective film 39 formed of SiN is laminated on the interlayer film 38. In the interlayer film 38 and the surface protective film 39, a pad opening 40 is formed that exposes the aluminum wire 36 as an electrode pad for electrical connection with an external portion.

The semiconductor device 1 has an MIM capacitor 41.

The MIM capacitor 41 includes a lower electrode 22 formed of a portion of the copper wire 23, a capacitive film 25 formed of a portion of the diffusion preventing film 24 and having both a function as a diffusion preventing film and a function as a capacitive film, and an upper electrode 26 formed of titanium nitride and laminated on the capacitive film 25. The upper electrode 26 opposes the lower electrode 22 with sandwiching the capacitive film 25. Accordingly, an MIM structure is formed of: a metal (lower electrode 22)—an insulator (capacitive film 25)—a metal (upper electrode 26). The capacitive film 25 and the upper electrode 26 are coated with the interlayer film 27.

In the interlayer film 38, an aluminum wire 55 of a predetermined pattern and made of a metal having aluminum as a main component (for example, an aluminum-copper alloy) is formed at a portion opposing the MIM capacitor 41. The aluminum wire 55 is sandwiched by a barrier film in a two-layer structure having a titanium nitride barrier film 54 formed of titanium nitride and deposited onto a lower surface of the aluminum wire 55, and a titanium barrier film 53 formed of titanium and deposited onto the titanium nitride barrier film 54, and a titanium nitride barrier film 56 formed of titanium nitride and deposited onto an upper surface of the aluminum wire 55 (hereinafter, unless specified otherwise, the aluminum wire 55 includes the titanium barrier film 53, the titanium nitride barrier film 54, and the titanium nitride barrier film 56). In place of the barrier film in the two-layer structure having the titanium barrier film 53 and the titanium nitride barrier film 54, a single-layer barrier film made of titanium nitride may be formed.

In the interlayer film 27, a contact hole 29 for penetrating through the interlayer film 27 in the film thickness direction is formed at a portion where the MIM capacitor 41 and the aluminum wire 55 oppose each other.

A conductive, laminated barrier film 31 is deposited onto side surfaces of the contact hole 29 and a portion of the upper electrode 26 that faces an interior of the contact hole 29. The laminated barrier film 31 is formed, for example, of the same material as the laminated barrier film 30.

An upper contact 33 formed of tungsten is embedded in the contact hole 29 deposited with the laminated barrier film 31. The upper contact 33 fills up the contact hole 29 and an upper surface thereof is flush with the upper surface of the interlayer film 27. With the upper contact 33, the aluminum wire 55 and the upper electrode 26 are electrically connected.

FIG. 2 is an enlarged view of a portion surrounded by a circle A in FIG. 1.

A specific arrangement of the laminated barrier film 30 shall now be described with reference to FIG. 2.

The laminated barrier film 30 is interposed between the copper wire 23 and the tungsten plug 32 and has a laminated structure formed by lamination of a plurality of layers. In the present embodiment, the laminated barrier film 30 has a four-layer laminated structure made of a tantalum barrier film 42, a tantalum nitride barrier film 43, a titanium barrier film 44, and a titanium nitride barrier film 45.

The tantalum barrier film 42 is formed of tantalum and is deposited onto the side surface of the via hole 28 and an upper surface of the copper wire 23. By being deposited onto the upper surface of the copper wire 23, the tantalum barrier film 42 is put in contact with the copper wire 23. The tantalum barrier film 42 has a film thickness, for example, of 2 nm to 20 nm.

The tantalum nitride barrier film 43 is formed of tantalum nitride and is laminated onto the tantalum barrier film 42. The tantalum nitride barrier film 43 has a film thickness, for example, of 2 nm to 20 nm.

The titanium barrier film 44 is formed of titanium and is laminated onto the tantalum nitride barrier film 43. The titanium barrier film 44 has a film thickness, for example, of 3 nm to 30 nm.

The titanium nitride barrier film 45 is formed of titanium nitride and is laminated onto the titanium barrier film 44. The titanium nitride barrier film 45 constitutes an uppermost layer of the laminated barrier film 30 and is formed to be in contact with a surface of the tungsten plug 32. The titanium nitride barrier film 45 has a film thickness, for example, of 2 nm to 20 nm.

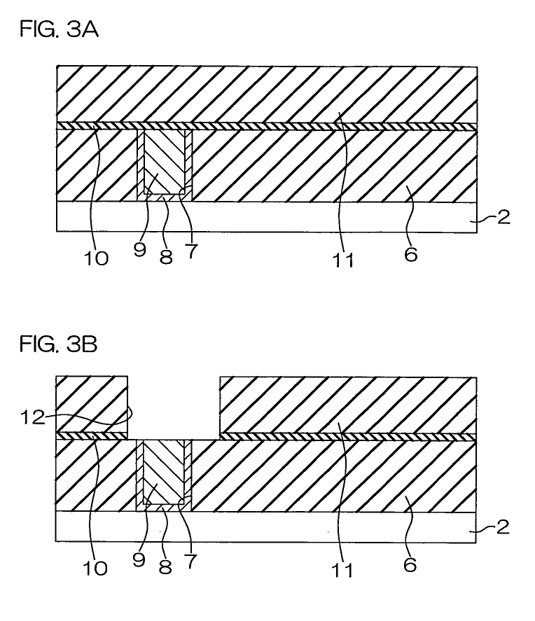

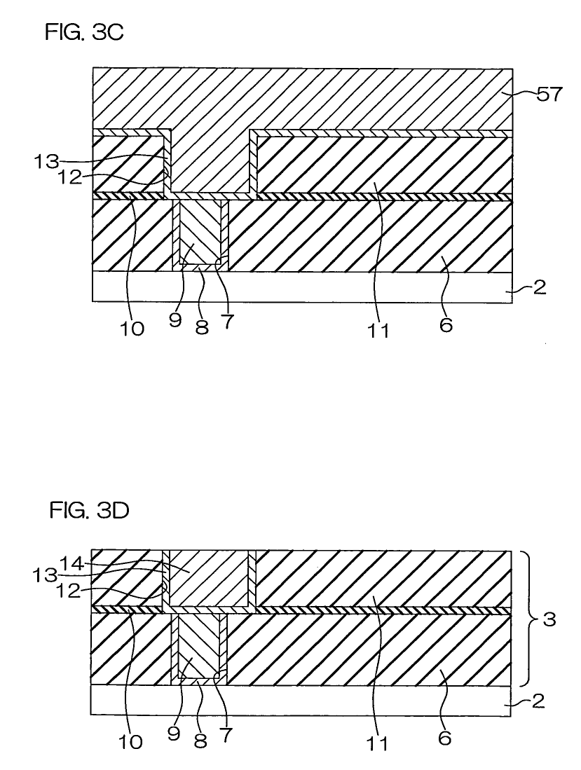

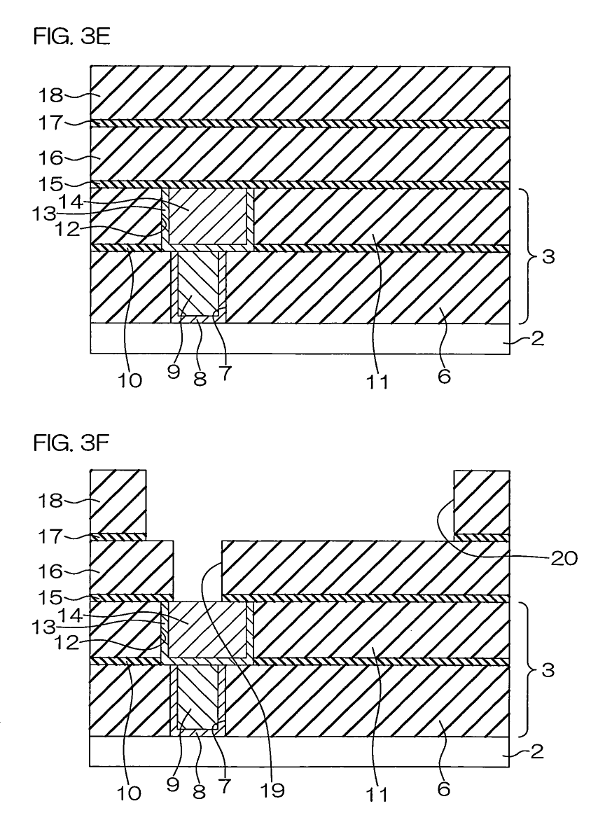

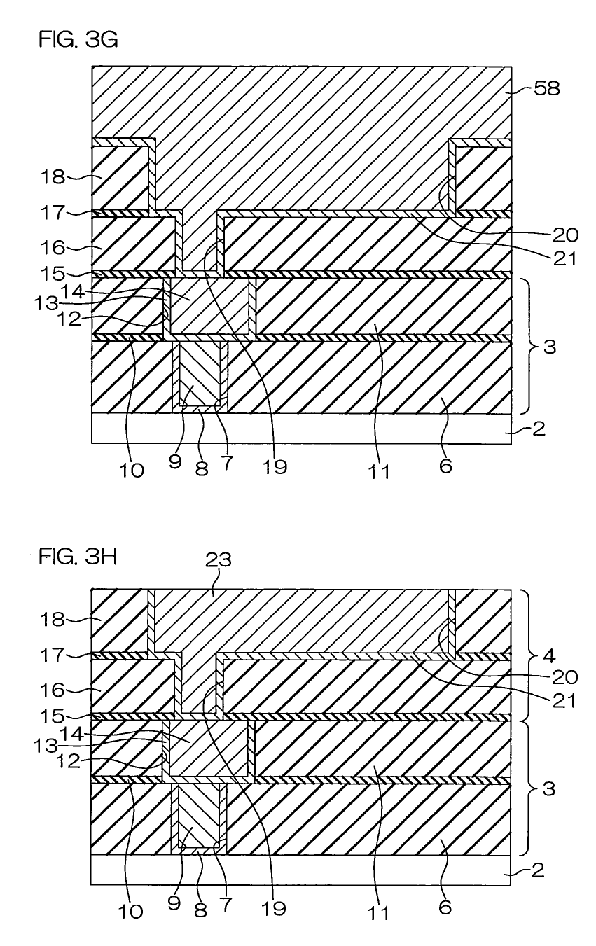

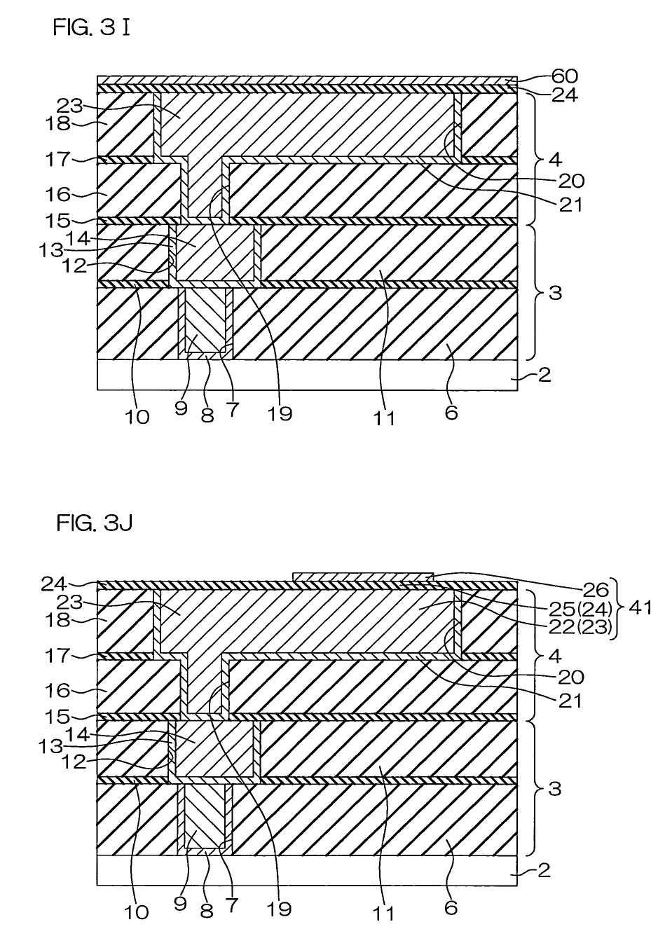

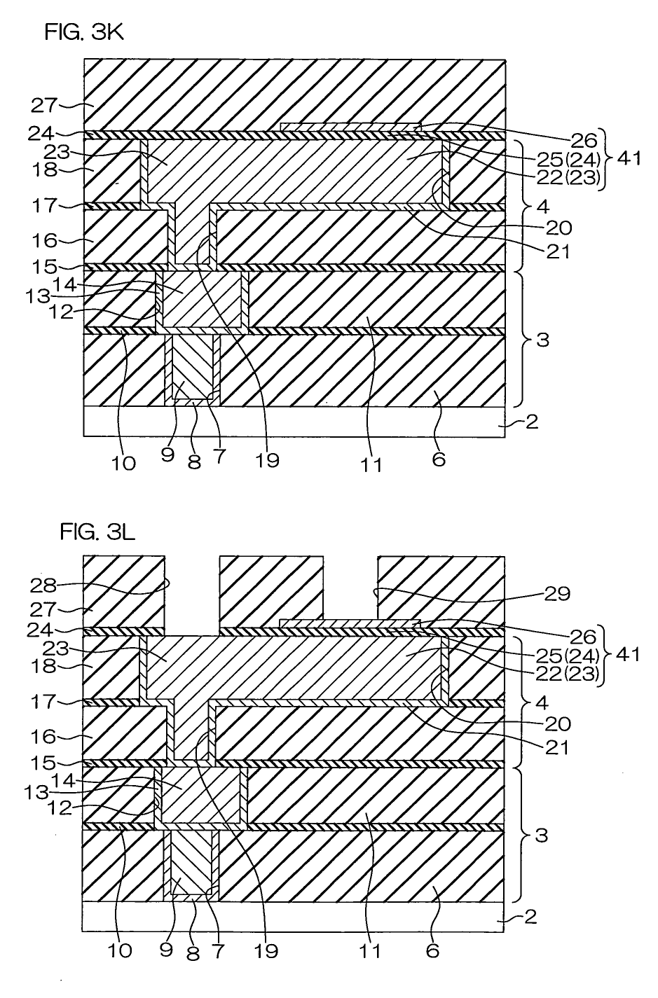

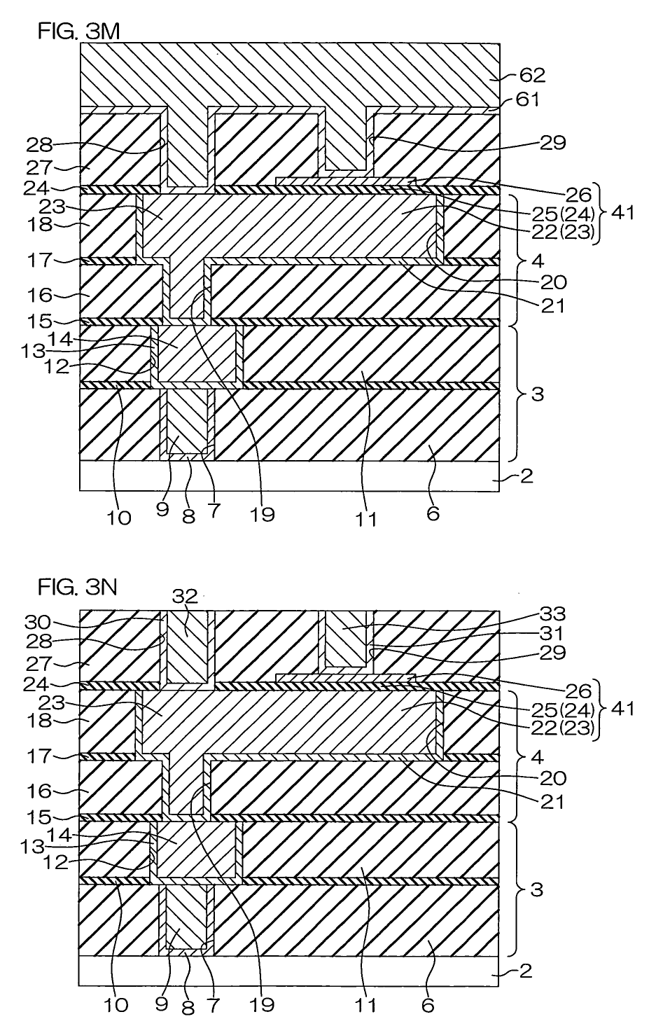

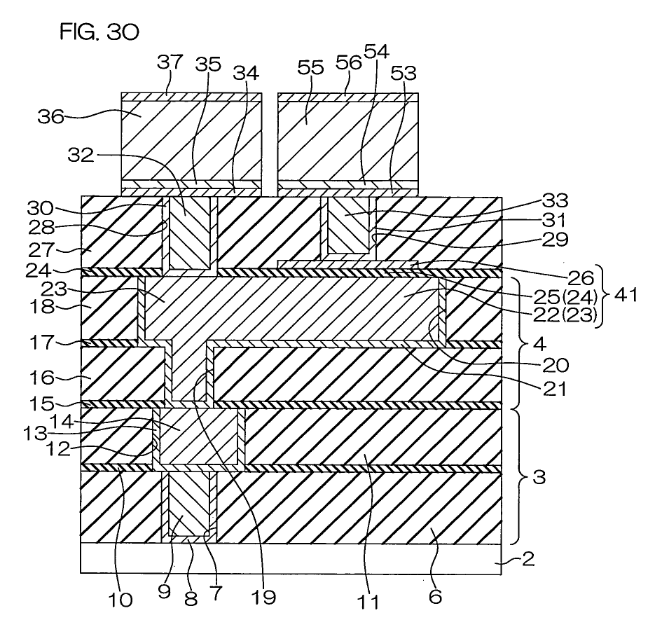

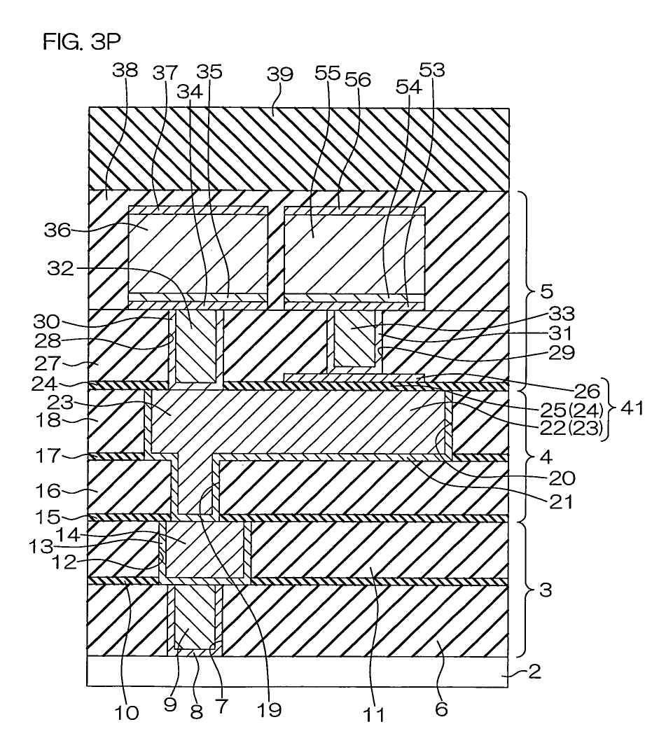

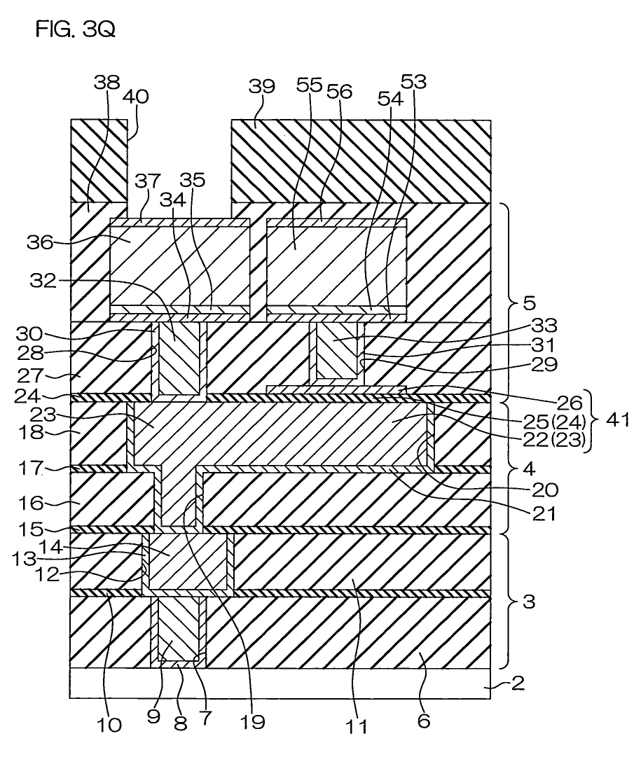

FIGS. 3A to 3Q are stepwise schematic sectional views showing a method for manufacturing the semiconductor device 1.

The method for manufacturing the semiconductor device 1 shall now be described with reference to FIGS. 3A to 3Q.

In manufacturing the semiconductor device 1, first, the interlayer film 6 is formed on the semiconductor substrate 2, for example, by a CVD (chemical vapor deposition) method.

The contact hole 7 is then formed in the interlayer film 6 by a known photolithography technique and etching technique (for example, dry etching). After the contact hole 7 is formed, the titanium nitride barrier film 8 is deposited, for example, by the CVD method onto the entire surface of the interlayer film 6 including the interior of the contact hole 7. By using the CVD method to form the titanium nitride barrier film 8, the titanium nitride barrier film 8 can be deposited onto the interlayer film 6 with good coverage even when the contact hole 7 is small in opening diameter.

A tungsten film formed of tungsten is then deposited on the titanium nitride barrier film 8, for example by the CVD method using WF₆ gas (tungsten hexafluoride gas) (this method shall hereinafter be referred to as the “W-CVD method”).

The tungsten film and the titanium nitride barrier film 8 are then polished by a CMP (chemical mechanical polishing) method. This polishing treatment removes, all unnecessary portions of the tungsten film and the titanium nitride barrier film 8 that are formed outside the contact hole 7 consequently, the tungsten film thereby becomes the tungsten plug 9. The diffusion preventing film 10 and the interlayer film 11 are then formed, for example, by the CVD method on the interlayer film 6 including the upper surface of the tungsten plug 9.

Then as shown in FIG. 3B, the wiring groove 12 of the predetermined pattern that penetrates through the interlayer film 11 and the diffusion preventing film 10 is formed by the known photolithography technique and etching technique (for example, dry etching).

Then as shown in FIG. 3C, the tantalum barrier film 13 is deposited, for example, by the CVD method onto the entire surface of the interlayer film 11 including the interior of the wiring groove 12. After the tantalum barrier film 13 is deposited, a copper film 57 formed of a metal having copper as a main component is formed on the tantalum barrier film 13, for example, by a plating method. The copper film 57 is formed in a thickness to fill up the wiring groove 12 and cover the entire surface of the tantalum barrier film 13.

Then as shown in FIG. 3D, the copper film 57 and the tantalum barrier film 13 are polished by the CMP method. The portion of the copper film 57 embedded in the wiring groove 12 thereby becomes the copper wire 14. The first wiring layer 3 is thus obtained.

After the copper wire 14 is formed, the diffusion preventing film 15, the interlayer film 16, the etch stop film 17, and the interlayer film 18 are formed in that order, for example, by the CVD method on the interlayer film 11 including the upper surface of the copper wire 14, as shown in FIG. 3E.

Then as shown in FIG. 3F, by a so-called dual damascene forming technique using the known photolithography technique and etching technique (for example, dry etching), the wiring groove 20 of the predetermined pattern, penetrating through the interlayer film 18 and the etch stop film 17, and the via hole 19 penetrating through the interlayer film 16 and the diffusion preventing film 15 are formed.

Then as shown in FIG. 3G, the tantalum-based barrier film 21 is deposited, for example, by the CVD method on the entire surface of the interlayer film 18 including the interior of the wiring groove 20.

After the tantalum barrier film 21 is deposited, a copper film 58 formed of a metal having copper as a main component is formed on the tantalum barrier film 21, for example, by the plating method. The copper film 58 is formed in a thickness to fill up the wiring groove 20 and cover the entire surface of the tantalum barrier film 21.

Then as shown in FIG. 3H, the copper film 58 and the tantalum barrier film 21 are polished by the CMP method. The portion of the copper film 58 embedded in the wiring groove 20 thereby becomes the copper wire 23. The second wiring layer 4 is thus obtained.

After the copper wire 23 is formed, the diffusion preventing film 24 (capacitive film 25) and a titanium nitride film 60 are formed in that order, for example, by the CVD method on the interlayer film 18 including the upper surface of the copper wire 23, as shown in FIG. 3I.

Then as shown in FIG. 3J, by the known photolithography technique and etching technique (for example, dry etching), the titanium nitride film 60 is etched, and the etching is stopped on the diffusion preventing film 24. The MIM capacitor 41 is thereby formed.

Then as shown in FIG. 3K, the interlayer film 27 is formed, for example, by the CVD method on the diffusion preventing film 24 including a region above the MIM capacitor 41.

The via hole 28 penetrating through the interlayer film 27 and the diffusion preventing film 24 and reaching the upper surface of the copper wire 23, and the contact hole 29 penetrating through the interlayer film 27 and reaching the upper surface of the upper electrode 26 are then formed by the known photolithography technique and etching technique (for example, dry etching).

After the via hole 28 and the contact hole 29 are formed, a laminated barrier film 61 is formed by laminating a tantalum film formed of tantalum, a tantalum nitride film formed of tantalum nitride, a titanium film formed of titanium, and a titanium nitride film formed of titanium nitride for example, by the CVD method on the entire surface of the interlayer film 27 including the interiors of the holes, as shown in FIG. 3M. By using the CVD method to form the laminated barrier film 61, the laminated barrier film 61 can be deposited onto the interlayer film 27 with good coverage even when the via hole 28 and the contact hole 29 are small in opening diameter. Thereafter, a tungsten film 62 formed of tungsten is deposited on the laminated barrier film 61, for example, by the W-CVD method.

Then as shown in FIG. 3N, the tungsten film 62 and the laminated barrier film 61 are polished by the CMP method. The portion of the laminated barrier film 61 deposited on the side surfaces of the via hole 28 and the upper surface of the copper wire 23 therefore becomes the laminated barrier film 30, and the portion of the laminated barrier film 61 deposited on the side surfaces of the contact hole 29 and the upper surface of the upper electrode 26 becomes the laminated barrier film 31. The portion of the tungsten film 62 remaining inside the via hole 28 becomes the tungsten plug 32 and the portion remaining inside the contact hole 29 becomes the upper contact 33.

Then as shown in FIG. 3O, a titanium film formed of titanium, a titanium nitride film formed of titanium nitride, an aluminum film formed of a metal having aluminum as a main component, and a titanium nitride film formed of titanium nitride are formed sequentially on the interlayer film 27, for example, by a sputtering method. Accordingly, a laminated film is formed that includes the titanium film, the titanium nitride film, the aluminum film, and the titanium nitride film.

The laminated film is then formed to a predetermined pattern by the known photolithography technique and etching technique (for example, dry etching). The aluminum wire 36 and the aluminum wire 55 are thereby formed on the interlayer film 27.

Then as shown in FIG. 3P, the interlayer film 38 is formed, for example, by the CVD method on the interlayer film 27 including the regions above the aluminum wire 36 and the aluminum wire 55. The third wiring layer 5 is there by obtained. Furthermore, the surface protective film 39 is formed on the interlayer film 38, for example, by the CVD method.

Then as shown in FIG. 3Q, the pad opening 40 penetrating through the surface protective film 39 and the interlayer film 38 and exposing the aluminum wire 36 is formed by the known photolithography technique and etching technique (for example, dry etching).

The semiconductor device 1 made in the three-layer structure of the first wiring layer 3, the second wiring layer 4, and the third wiring layer 5, is thereby obtained.

As described above, in the semiconductor device 1, the titanium nitride barrier film 45 is the portion of the laminated barrier film 30 that contacts the tungsten plug 32. Thus even when WF₆ gas is supplied onto the laminated barrier film 30 (see FIG. 3M), the WF₆ gas can be prevented from diffusing into the interlayer film 27 and corroding the interlayer film 27.

The tungsten plug 32 contacts the titanium nitride barrier film 45, which is excellent in adhesion with tungsten in the laminated barrier film 30. Thus adhesion of the laminated barrier film 30 and the tungsten plug 32 can be improved. Meanwhile, the copper wire 23 contacts the tantalum barrier film 42, which is excellent in adhesion with copper in the laminated barrier film 30. Thus adhesion of the laminated barrier film 30 and the copper wire 23 can be improved. Accordingly, film peeling of the laminated barrier film 30 can be prevented. Therefore, occurrence of stress migration can be prevented. Furthermore, because the titanium nitride barrier film 45 and the copper wire 23 are not in contact and because tantalum has low reactivity with copper, corrosion of the copper wire 23 does not occur. Thus occurrence of electromigration can be prevented.

Consequently, reliability of connection of the copper wire 23 (second wiring layer 4) and the aluminum wire 36 (third wiring layer 5) can be improved.

Further, the tantalum nitride barrier film 43 is interposed between the tantalum barrier film 42 and the titanium nitride barrier film 45. In comparison to tantalum, tantalum nitride has an excellent ability to prevent diffusion of copper into SiO₂ or other insulating material (copper diffusion preventing performance). Therefore, diffusion of the copper of the copper wire 23 into the interlayer film 27 can be prevented.

Yet further, the titanium barrier film 44 is interposed between the tantalum nitride barrier film 43 and the titanium nitride barrier film 45. Titanium has excellent adhesion with tantalum nitride and titanium nitride. Therefore, adhesion of the tantalum nitride film 43 and the titanium nitride film 45 can be improved. Consequently, film peeling of the laminated barrier film 30 can be further prevented.

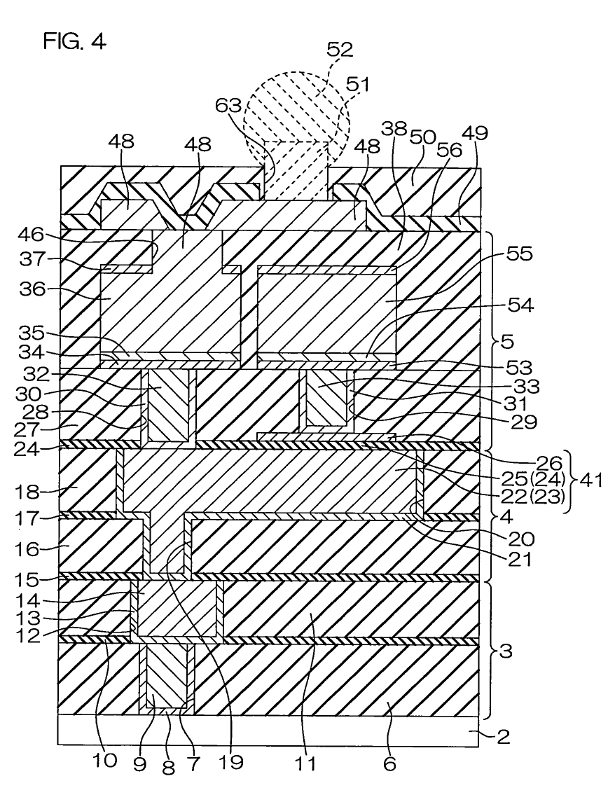

FIG. 4 is a schematic sectional view showing an arrangement of a semiconductor device 47 according to a second embodiment of the present invention. In FIG. 4, portions corresponding to portions shown in FIG. 1 are provided with the same reference symbols as those of FIG. 1.

In the arrangement shown in FIG. 4, the semiconductor device 47 is a semiconductor device to which a WL-CSP (wafer level-chip size package) technique is applied.

In the semiconductor device 47, a penetrating hole 46, reaching the aluminum wire 36, is formed in the interlayer film 38. A portion of the aluminum wire 36 facing the penetrating hole 46 is exposed via the penetrating hole 46. An aluminum rewire 48 is connected to the aluminum wire 36, having aluminum as a main component and drawn out on the surface of the interlayer film 38 via the penetrating hole 46. A portion of the aluminum rewire 48 drawn out on the surface of the interlayer film 38 is coated with a surface protective film 49 formed of SiN.

A protective film 50 formed of polyimide is laminated on the surface protective film 49. In the protective film 50 and the surface protective film 49, a connection opening 63 is formed that penetrates through the films in the film thickness direction. A portion of the aluminum rewire 48 that faces the connection opening 63 is exposed via the connection opening 63.

A post 51 formed of a material having copper as a main component is connected to the exposed aluminum rewire 48 via the connection opening 63.

An end of the post 51 at an opposite side of a side connected to the aluminum rewire 48 projects from the protective film 50. The projecting portion of the post 51 is connected to a solder bump 52 for electrical connection with an external portion.

The same effects as those of the semiconductor device 1 are also exhibited by the arrangement shown in FIG. 4.

In the semiconductor device 1 shown in FIG. 1 and the semiconductor device 47 shown in FIG. 4, the tungsten plug 32 formed of tungsten is employed as the plug for connecting the aluminum wire 36 (upper wire) and the copper wire 23 (lower wire).

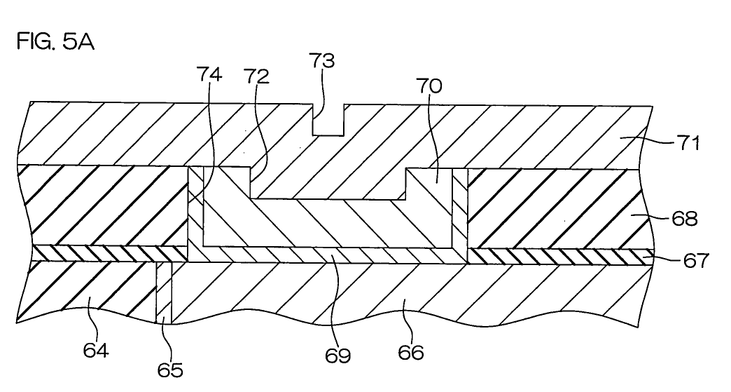

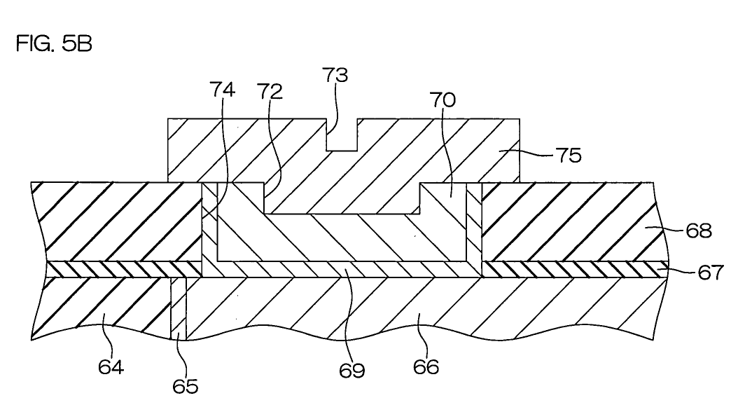

FIGS. 5A and 5B are schematic sectional views for describing a method for forming a structure connecting an aluminum wire (upper wire) and a copper wire (lower wire) that are connected with a tungsten plug.

To connect the upper wire and the lower wire using the tungsten plug, first, for example, a copper wire 66 (lower wire) having copper as a main component is embedded via a barrier film 65 (for example, the tantalum barrier film 21 in the embodiments) in a surface layer portion of an interlayer film 64 formed of SiO₂.

A diffusion preventing film 67 formed of SiC and an interlayer film 68 formed of SiO₂ are then laminated on the interlayer film 64. Next, a via hole 74 penetrating through the interlayer film 68 and the diffusion preventing film 67 is formed at portions of the films that oppose the copper wire 66.

Thereafter, a barrier film (for example, the laminated barrier film 61 in the embodiment) and a tungsten film (for example, the tungsten film 62 in the embodiment) are laminated on the entire surface of the interlayer film 68 including an interior of the via hole 74, for example, by a CVD method.

After the barrier film and the tungsten film are laminated, all portions of these films outside the interlayer film 68 are polished. Accordingly, the barrier film remaining inside the via hole 74 thereby becomes a barrier film 69, and the tungsten film remaining inside the via hole 74 becomes a tungsten plug 70. The tungsten plug 70 is formed to have a recess 72 that is recessed with respect to a surface of the interlayer film 68.

An aluminum film 71 is then sputtered onto the interlayer film 68. Because the recess 72 is formed on the tungsten plug 70, the aluminum film 71 is formed to a shape having a recess 73 at a portion immediately above the recess 72.

The aluminum film 71 is then patterned to a predetermined wiring pattern by the photolithography technique, and an aluminum wire 75 (upper wire) of the predetermined pattern is obtained as shown in FIG. 5B. In patterning the aluminum film 71, the aluminum film 71 may be patterned using the recess 73 of the aluminum film 71 as a mark.

Thus in the semiconductor device having the same connection structure as the connection structure of the aluminum wire 75 and the copper wire 66 that are connected with the tungsten plug 70, that is, in the semiconductor device 1 shown in FIG. 1 and the semiconductor device 47 shown in FIG. 4, the upper wire (for example, the aluminum wire 36 in FIGS. 1 and 4) formed on the tungsten plug can be patterned readily.

Although a plurality of embodiments of the present invention are described above, the present invention can also be put into practice in other forms.

For example, in the embodiment, the laminated barrier film 30 is made of the four-layer structure of the tantalum barrier film 42, the tantalum nitride barrier film 43, the titanium barrier film 44, and the titanium nitride barrier film 45. However, as long as the film in contact with the copper wire 23 is a tantalum barrier film and the film in contact with the tungsten plug 32 is a titanium nitride barrier film, the laminated structure may have an arrangement such as those described in 1 to 5 below.

(Laminated Structure of the Laminated Barrier Film 30)
1. Copper wire 23/tantalum barrier film/tantalum nitride barrier film/tantalum barrier film/titanium barrier film/titanium nitride barrier film/tungsten plug 32
2. Copper wire 23/tantalum barrier film/tantalum nitride barrier film/tantalum barrier film/titanium nitride barrier film/tungsten plug 32
3. Copper wire 23/tantalum barrier film/tantalum nitride barrier film/titanium nitride barrier film/tungsten plug 32
4. Copper wire 23/tantalum barrier film/titanium barrier film/titanium nitride barrier film/tungsten plug 32
5. Copper wire 23/tantalum barrier film/titanium nitride barrier film/tungsten plug 32

In a structure, such as laminated structure 1 and laminated structure 2 among the laminated structures 1 to 5, where a tantalum nitride barrier film is sandwiched by tantalum barrier films, the copper diffusion preventing performance of the laminated barrier film 30 can also be improved.

Further, in the embodiments described above, the wires in the third wiring layer 5 at the uppermost layer are the aluminum wire 36 and the aluminum wire 55 that have aluminum as the main component. However, for example, copper wires, made of a metal having copper as a main component may be used in place of these aluminum wires.

In the above-described embodiments, the respective interlayer films (6, 11, 16, 18, 27, and 38) are formed using SiO₂ . However, these may be formed using a low dielectric constant material (low-k material), such as SiOC, SiOF.

In the above-described embodiments, the respective diffusion preventing films (10, 15, and 24) and the etch stop film 17 are formed using SiC. However these may be formed using SiN.

Although embodiments of the present invention are described in detail above, these are merely specific examples used for clarifying the technical features of the present invention. The present invention should not be interpreted limitative to these specific examples, and the spirit and scope of the present invention are limited only by the attached claims.

The present application corresponds to Japanese Patent Application No. 2007-145808 filed with the Japan Patent Office on May 31, 2007 and the entire disclosure of this application is incorporated herein by reference.

What is claimed is:

1. A semiconductor device comprising:
a lower wire having copper as a main component;
an insulating film formed on the lower wire;
an upper wire formed on the insulating film;
a tungsten plug penetrating through the insulating film and formed of tungsten for electrically connecting the lower wire and the upper wire; and
a barrier layer interposed between the lower wire and the tungsten plug;
the barrier layer including a tantalum film contacting the lower wire and a titanium nitride film contacting the tungsten plug.

2. The semiconductor device according to claim 1, wherein
the barrier layer further includes a tantalum nitride film interposed between the tantalum film and the titanium nitride film.

3. The semiconductor device according to claim 2, wherein
the barrier layer further includes a titanium film interposed between the tantalum nitride film and the titanium nitride film.

4. The semiconductor device according to claim 1, wherein
the barrier layer further includes a titanium film interposed between the tantalum film and the titanium nitride film.

5. The semiconductor device according to claim 1, wherein
the upper wire is an aluminum wire having aluminum as a main component.

6. The semiconductor device according to claim 2, wherein
the upper wire is an aluminum wire having aluminum as a main component.

7. The semiconductor device according to claim 3, wherein
the upper wire is an aluminum wire having aluminum as a main component.

8. The semiconductor device according to claim 4, wherein
the upper wire is an aluminum wire having aluminum as a main component.
